(19) United States
(12) Patent Application Publication
(10) Pub. No.: US 2020/0378002 A1
(43) Pub. Date: Dec. 3, 2020

(54) DEPOSITION APPARATUS AND DEPOSITION METHOD

(71) Applicant: CANON KABUSHIKI KAISHA, Tokyo (JP)

(72) Inventors: Takashi Tsuboi, Fujisawa-shi (JP); Yasushi Kawasumi, Fujisawa-shi (JP)

(21) Appl. No.: 16/879,038

(22) Filed: May 20, 2020

(30) Foreign Application Priority Data
May 29, 2019 (JP) 2019-100726

(51) Int. Cl. C23C 16/458; C23C 16/455; C23C 16/34; C23C 16/30

(52) U.S. Cl. CPC C23C 16/4584; C23C 16/45525; H01L 51/56; C23C 16/308; C23C 16/345

(57) ABSTRACT

A deposition apparatus comprising a substrate holder for holding a substrate, a conveying mechanism for conveying the substrate in a horizontal attitude to insert/remove the substrate into/from the substrate holder, a rotating mechanism for changing an attitude of the substrate, a chamber for accommodating the rotated substrate holder to set the substrate in a vertical attitude and to perform a deposition process, and a control unit configured to perform first control to cause the conveying mechanism to make the substrate holder hold the substrate at a first position when inserting the substrate into the substrate holder before the deposition process, and to perform second control to cause the conveying mechanism to receive the substrate from the substrate holder at a second position located more backward than the first position when removing the substrate from the substrate holder after the deposition process.

### BACKGROUND OF THE INVENTION

### Field of the Invention

The present invention mainly relates to a deposition apparatus.

### Description of the Related Art

Japanese Patent Laid-Open No. 2016-503462 discloses the arrangement of a deposition apparatus including a conveying mechanism that conveys a substrate, a substrate holder that can hold a substrate, a rotating mechanism that rotates the substrate holder, and a chamber that accommodates the substrate holder and performs a deposition process for a substrate. The conveying mechanism conveys a substrate in a horizontal attitude and removably inserts the substrate into the substrate holder. The rotating mechanism can change the attitude of a substrate held by the substrate holder by rotating the substrate holder. The rotating mechanism can change, for example, one of the horizontal attitude and the vertical attitude to the other. The chamber accommodates the substrate holder together with a substrate in the vertical attitude. In this state, a deposition process is performed with respect to the substrate. After the deposition process, the rotating mechanism changes the attitude of the processed substrate to the horizontal attitude by rotating the substrate holder again. The conveying mechanism removes the substrate and conveys it to the next step.

The above arrangement disclosed in Japanese Patent Laid-Open No. 2016-503462 is also required to improve the quality (yield) of substrates.

### SUMMARY OF THE INVENTION

The present invention has an exemplary object to provide a technique advantageous in improving the quality of a substrate when performing a deposition process by using a deposition apparatus.

One aspect of the present invention relates to a deposition apparatus, and the deposition apparatus comprising a substrate holder configured to be able to hold a substrate, a conveying mechanism configured to convey the substrate in a horizontal attitude and to be able to insert and remove the substrate into and from the substrate holder, a rotating mechanism configured to change an attitude of the substrate held by the substrate holder by rotating the substrate holder, a chamber configured to accommodate the substrate holder rotated by the rotating mechanism so as to set the substrate in a vertical attitude and to perform a deposition process with respect to the substrate, and a control unit, wherein the control unit performs first control to cause the conveying mechanism to make the substrate holder hold the substrate at a first position when inserting the substrate into the substrate holder before the deposition process, and performs second control to cause the conveying mechanism to receive the substrate from the substrate holder at a second position located more backward than the first position when removing the substrate from the substrate holder after the deposition process.

Further features of the present invention will become apparent from the following description of exemplary embodiments (with reference to the attached drawings).

### BRIEF DESCRIPTION OF THE DRAWINGS

FIG. 1 is a schematic view for explaining an example of the arrangement of a deposition apparatus;

FIG. 2A is a schematic view for explaining an example of a control method for the deposition apparatus;

FIG. 2B is a schematic view for explaining the example of the control method for the deposition apparatus;

FIG. 2C is a schematic view for explaining the example of the control method for the deposition apparatus;

FIG. 2D is a schematic view for explaining the example of the control method for the deposition apparatus;

FIG. 2E is a schematic view for explaining the example of the control method for the deposition apparatus;

FIG. 2F is a schematic view for explaining the example of the control method for the deposition apparatus;

FIG. 2G is a schematic view for explaining the example of the control method for the deposition apparatus;

FIG. 2H is a schematic view for explaining the example of the control method for the deposition apparatus; and

FIG. 3 is a schematic view for explaining an example of the arrangement of a manufacturing system.

### DESCRIPTION OF THE EMBODIMENTS

Hereinafter, embodiments will be described in detail with reference to the attached drawings. Note, the following embodiments are not intended to limit the scope of the claimed invention. Multiple features are described in the embodiments, but limitation is not made an invention that requires all such features, and multiple such features may be combined as appropriate. Furthermore, in the attached drawings, the same reference numerals are given to the same or similar configurations, and redundant description thereof is omitted.

### First Embodiment

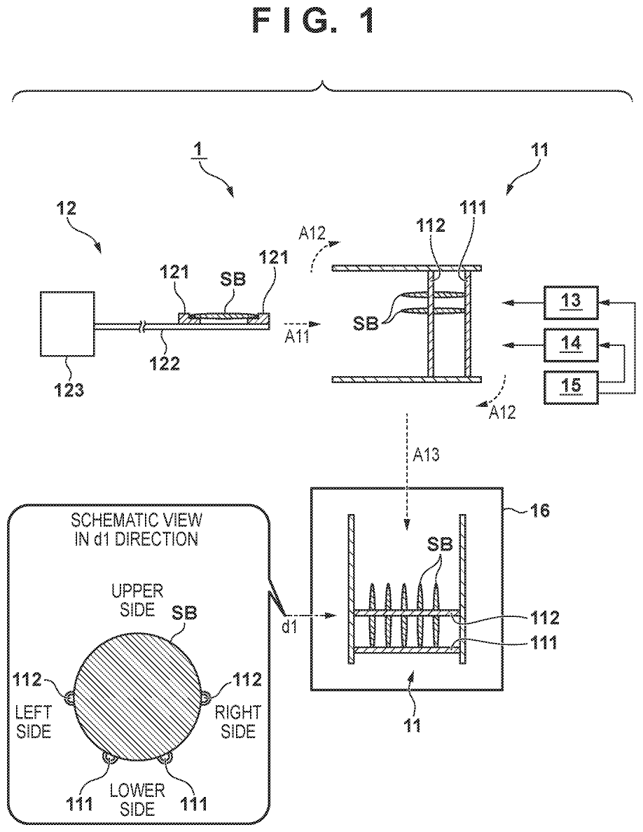

FIG. 1 is a schematic view showing an example of the arrangement of a deposition apparatus 1 according to an embodiment. The deposition apparatus 1 includes a substrate holder 11, a conveying mechanism 12, a moving mechanism 13, a rotating mechanism 14, a control unit 15, and a chamber 16. The substrate holder 11 is configured to be able to hold one or more substrates SB. According to this embodiment, the substrate holder 11 can hold a plurality of (for example, 25) substrates SB. The substrate SB is made of a predetermined plate material such as a base material (for example, a wafer made of silicon or the like) for manufacturing a semiconductor device or a base material (for example, a glass substrate) for manufacturing an electronic device. The substrate holder 11 includes first supporting portions 111 and second supporting portions 112 fixed to the inner wall of the housing of the substrate holder 11. Although described in detail later, this arrangement allows the substrate holder 11 to hold the substrate SB.

The conveying mechanism 12 includes a receiving portion 121, an arm 122, and a driving unit 123. The receiving portion 121 has a placement surface and can place the substrate SB on the placement surface. The arm 122 is configured, for example, to be extensible, and supports the receiving portion 121 at an end portion. The driving unit 123 moves the position of the receiving portion 121 in the horizontal direction by extending/contracting the arm 122. This arrangement allows the conveying mechanism 12 to access the substrate holder 11. The conveying mechanism 12 conveys the substrates SB one by one in the horizontal attitude. This makes it possible to removably insert the substrate SB into the substrate holder 11. That is, the conveying mechanism 12 sequentially inserts the plurality of substrates SB one by one into the substrate holder 11 in the horizontal attitude and causes the substrate holder 11 to hold each substrate SB. The conveying mechanism 12 also sequentially receives the plurality of substrates SB one by one from the substrate holder 11 in the horizontal attitude.

The moving mechanism 13 is a lifting mechanism that vertically moves the substrate holder 11. The moving mechanism 13 can vertically adjust the position at which the conveying mechanism 12 accesses the substrate holder 11. For example, after the conveying mechanism 12 inserts one substrate SB into the substrate holder 11 as indicated by an arrow A11, the moving mechanism 13 moves the substrate holder 11 upward in this state. This causes the substrate holder 11 to hold the substrate SB supported by the supporting portions 111 and 112. Another embodiment may be configured such that the conveying mechanism 12 can further move in the vertical direction and alternatively/collaterally causes the substrate holder 11 to hold the substrate SB by moving the substrate SB downward.

The rotating mechanism 14 is configured to be able to rotate the substrate holder 11. This makes it possible to change the attitude of the substrate SB held by the substrate holder 11. For example, as indicated by an arrow A12, the rotating mechanism 14 rotates the substrate holder 11 to move the supporting portions 111 below the supporting portions 112. This changes the attitude of each substrate SB from the horizontal attitude to the vertical attitude. Although the angle through which the substrate holder 11 is rotated by the rotating mechanism 14 is about 90°, the rotational angle of the substrate holder 11 may fall within the range of 85° to 95° or 80° to 100°.

In this case, the horizontal attitude indicates a state in which the upper surface of the substrate SB is substantially horizontal to the horizontal direction, and includes, for example, an attitude in which the angle defined by the upper surface of the substrate SB and the horizontal direction falls within the range of −5° to +5°. The vertical attitude indicates a state in which the upper surface of the substrate SB is substantially horizontal to the vertical direction, and includes, for example, an attitude in which the angle defined by the upper surface of the substrate SB and the vertical direction falls within the range of −5° to +5°.

The control unit 15 controls the driving of each element of the deposition apparatus 1, and can control, for example, the conveying mechanism 12, the moving mechanism 13, and the rotating mechanism 14. A deposition process by the deposition apparatus 1 is mainly implemented by each element of the control unit 15. The function of the control unit 15 may also be implemented by a semiconductor device such as an ASIC (Application Specific Integrated Circuit) or PLD (Programmable Logic Device), that is, hardware. Alternatively, the function of the control unit 15 may be implemented by reading out and executing programs using a CPU (Central Processing Unit) and a memory, that is, software.

The chamber 16 is configured to be able to accommodate the substrate holder 11 and performs a deposition process with respect to the substrate SB held by the substrate holder 11. The moving mechanism 13 described above can move the substrate holder 11 between the accessible position of the conveying mechanism 12 and a position in the chamber 16. For example, after the substrate holder 11 is rotated by the rotating mechanism 14 so as to set each substrate SB in the vertical attitude, the substrate holder 11 is moved downward by the moving mechanism 13 and accommodated in the chamber 16. Thereafter, a known deposition process is performed in the chamber 16. Examples of the deposition process include CVD (Chemical Vapor Deposition) and ALD (Atomic Layer Deposition). One of these processes may be performed in the chamber 16.

As shown in FIG. 1 as a schematic view seen from a viewpoint in a direction dl in the chamber 16, the supporting portions 111 are positioned on a lower side of the substrate SB in the vertical attitude, and the supporting portions 112 are positioned on a lateral side of the substrate SB. From this viewpoint, the supporting portions 111 may be expressed as lower side supporting portions, and the supporting portions 112 may be expressed as lateral side supporting portions. This embodiment exemplifies a form in which one pair of the supporting portions 111 are provided on the left and right sides, and one pair of the supporting portions 112 are provided on the left and right sides. However, the number of such supporting portions is not limited to that exemplified in this case.

In this case, the substrate holder 11 is configured to be able to support the substrate SB in any state such as the horizontal attitude or the vertical attitude, and the supporting portions 111 and 112 may be provided with known arrangements. While the substrate holder 11 holds the substrate SB in the horizontal attitude, the supporting portions 111 are located on the opposite side to the side where the conveying mechanism 12 accesses with respect to the supporting portions 112.

In this embodiment, the chamber 16 is positioned below the accessible position of the conveying mechanism 12. Another embodiment may exemplify an aspect in which the chamber 16 is positioned above the accessible position of the conveying mechanism 12. In any of these forms, a deposition process can be implemented after the attitudes of the plurality of substrates SB are changed from the horizontal attitude to the vertical attitude by a relatively simple arrangement.

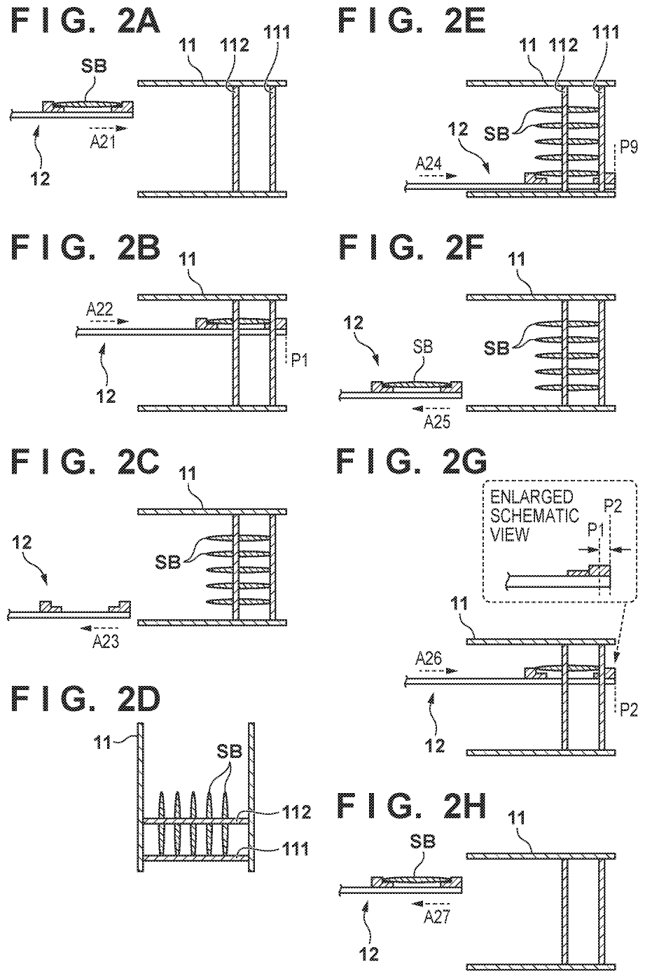

FIGS. 2A to 2H are schematic views for explaining each step in the control method for the deposition apparatus 1 described above, that is, a deposition method using the deposition apparatus 1.

In the step in FIG. 2A, as indicated by an arrow A21, the conveying mechanism 12 conveys the substrate SB toward the substrate holders 11. In the step in FIG. 2B, as indicated by an arrow A22, after the substrate SB is inserted into the substrate holder 11 together with the conveying mechanism 12, the conveying mechanism 12 is stopped at a predetermined position (first position) P1. In this state, the moving mechanism 13 moves the substrate holder 11 upward to make the supporting portions 111 and 112 support the substrate SB and make the substrate holder 11 hold the substrate SB.

Repeating the steps in FIGS. 2A and 2B makes the substrate holder 11 sequentially hold the plurality of substrates SB (although the number of substrates SB is five for the sake of illustrative simplicity, the number of substrates is not limited to this.) Assume that in this embodiment, the plurality of substrates SB are sequentially held on the substrate holder 11 from above. In this manner, the plurality of substrates SB each are positioned in the horizontal attitude and are held on the substrate holder 11 so as to be arranged in the vertical direction.

As indicated by an arrow A23 in FIG. 2C, after all the substrates SB are held on the substrate holder 11, the conveying mechanism 12 returns to the initial position (home position) and is set in a standby state.

In the step in FIG. 2D, the rotating mechanism 14 rotates the substrate holder 11 to change the attitude of each substrate SB from the horizontal attitude to the vertical attitude. That is, the plurality of substrates SB each are set in the vertical attitude and are held on the substrate holder 11 so as to be arranged in the horizontal direction. Thereafter, the moving mechanism 13 moves the substrate holder 11 into the chamber 16, together with the plurality of substrates SB held on the substrate holder 11, and a deposition process is executed with respect to the plurality of substrates SB.

After the completion of the deposition process, the moving mechanism 13 moves the substrate holder 11, together with the plurality of substrates SB held on the substrate holder 11, outside the chamber 16. The rotating mechanism 14 then rotates the substrate holder 11 to return the attitude of each substrate SB from the vertical attitude to the horizontal attitude. At this stage, the above substrate SB can also be expressed as a processed substrate. In the steps in FIGS. 2E to 2H, the conveying mechanism 12 sequentially removes the plurality of substrates SB from the substrate holder 11, and conveys each substrate to the next step.

In the step in FIG. 2E, as indicated by an arrow A24, the conveying mechanism 12 is made to access the substrate holder 11 and stop at a predetermined position P9. In this state, the moving mechanism 13 moves the substrate holder 11 downward to place a corresponding one of the plurality of substrates SB on the receiving portion 121 of the conveying mechanism 12. In the step in FIG. 2F, the conveying mechanism 12 conveys the substrate SB received by the receiving portion 121 and removes the substrate SB from the substrate holder 11, as indicated by an arrow A25.

By repeating the steps in FIGS. 2E and 2F, the plurality of substrates SB are sequentially removed from the substrate holder 11. Assume that in this embodiment, the plurality of substrates SB are sequentially removed from the substrate holder 11 from below.

In the step in FIG. 2G, the last one of the plurality of substrates SB (in this case, the substrate SB inserted into the substrate holder 11 in the steps in FIGS. 2A and 2B) is removed from the substrate holder 11. First of all, as indicated by an arrow A26, the conveying mechanism 12 is made to access the substrate holder 11 and stop at a predetermined position (second position) P2. In this state, the moving mechanism 13 moves the substrate holder 11 downward to place the substrate SB on the receiving portion 121 of the conveying mechanism 12. In the step in FIG. 2H, as indicated by an arrow A27, the conveying mechanism 12 conveys the substrate SB received by the receiving portion 121 to remove the substrate SB from the substrate holder 11. This completes the series of steps concerning the deposition process with respect to the plurality of substrates SB.

In the step in FIG. 2D, the substrate holder 11 rotates to change the attitude of the plurality of substrates SB held on the substrate holder 11 in the steps in FIGS. 2A to 2C, and hence the relative position of the substrates on the substrate holder 11 can change due to the influence of gravity. That is, after the step in FIG. 2D, the position of each substrate SB can move to a rear side (the opposite side to the side where the conveying mechanism 12 accesses) relative to the position of each substrate SB before the step in FIG. 2D. The movement amount of each substrate SB can depend on the arrangement of the substrate holder 11, for example, the number, material, positions, shapes, and the like of the supporting portions 111 and 112.

Accordingly, in the steps in FIGS. 2E to 2H, in order to suppress or reduce foreign substances that can accidentally occur when the substrate SB is removed from the substrate holder 11 (when the substrate SB is received by the receiving portion 121), it is necessary to properly place the substrate SB on the receiving portion 121. There is conceivable a method of increasing the area of the placement surface of the receiving portion 121 on which the substrate SB is to be placed in order to allow the receiving portion 121 to reliably receive the substrate SB. However, because this increases the contact area between the receiving portion 121 and the substrate SB, this can be a cause of the occurrence of the above foreign substances.

In this embodiment, the position of the receiving portion 121 is changed in accordance with the above movement amount (that is, the movement amount of the substrate SB depending on the influence of gravity when the substrate SB is set in the vertical attitude upon rotation of the substrate holder 11) at the time of receiving the substrate SB. For example, a stop position P2 of the conveying mechanism 12 in the step in FIG. 2G (when the substrate SB is removed from the substrate holder 11) is located more backward than a stop position P1 of the conveying mechanism 12 in the step in FIG. 2B (when the substrate SB is inserted into the substrate holder 11).

This can be summarized as follows from the viewpoint of the control unit 15. That is, in the steps in FIGS. 2A to 2C (before the deposition process in FIG. 2D), the control unit 15 causes the conveying mechanism 12 to access the position P1 to insert the substrate SB into the substrate holder 11 and hold the substrate SB (first control). Thereafter, in the steps in FIGS. 2E to 2H (after the deposition process in FIG. 2D), the control unit 15 causes the conveying mechanism 12 to access a position P2 located more backward than the position P1 and to receive the substrate SB from the substrate holder 11 (second control).

According to this embodiment, the substrate SB is properly placed on the receiving portion 121. This can make it difficult to cause the occurrence of the above foreign substances when the substrate SB is removed from the substrate holder 11 (when the substrate SB is received by the receiving portion 121). In addition, it is not necessary to increase the area of the above placement surface of the receiving portion 121. This embodiment can therefore improve the quality of the substrate SB when performing a deposition process by using the deposition apparatus 1. Note that the stop position P9 of the conveying mechanism 12 in the step in FIG. 2E (when another substrate SB is removed from the substrate holder 11) can substantially overlap the position P2 in the vertical direction.

The substrate SB may be inserted into the substrate holder 11 (see FIGS. 2A to 2C) so as to prevent the substrate SB from coming into contact with the substrate holder 11 in the horizontal direction, that is, prevent the edge portion of the substrate SB from coming into contact with the inner wall of the housing of the substrate holder 11. This prevents the substrate SB from being damaged and the generation of unexpected foreign substances at the time of inserting the substrate SB. Although it depends on the arrangements of the supporting portions 111 and 112 (for example, dimensions), when, for example, the substrate SB is inserted, a predetermined gap (for example, about 200 μm to 600 μm, preferably, about 450 μm to 550 μm) may be formed between the substrate SB and the inner wall of the housing. Likewise, the conveying mechanism 12 may convey the substrate SB and insert and remove the substrate SB into and from the substrate holder 11 without any interference with the substrate holder 11. Note that when the rotating mechanism 14 rotates the substrate holder 11 to set each substrate SB in the vertical attitude (see FIG. 2D), the substrate SB can come into contact with the inner wall of the housing upon reception of the influence of gravity. However, because the gap is relatively small, foreign substances that can accidentally occur can be suppressed or reduced.

### Experimental Example 1

In Experimental Example 1, as an example of the above embodiment, 25 silicon wafers as the substrates SB were prepared, and an aluminum oxide film (having a thickness of about 25 nm) was formed on each of the substrates SB in the procedure shown in FIGS. 2A to 2H using the deposition apparatus 1 (see FIG. 1). A deposition process by the deposition apparatus 1 was performed by ALD using trimethylaluminum (TMA) and water vapor (H₂O) at a substrate temperature of 250° C.

In this case, the rotational angle of the substrate holder 11 rotated by the rotating mechanism 14 when a deposition process was performed (see FIG. 2D) was 90°. When the substrate SB was inserted into the substrate holder 11 (see FIGS. 2A to 2C), a gap of about 500 μm was provided between the substrate SB and the inner wall of the housing. Accordingly, the stop position (for example, P2 or P9) of the conveying mechanism 12 at the time of removing the substrate SB from the substrate holder 11 (see FIGS. 2E to 2H) was located more backward by about 500 μm than the stop position (for example, P1) of the conveying mechanism 12 at the time of inserting the substrate SB.

In Experimental Example 1, a known measurement device (SP2 available from KLA-Tencor) measured that the number (average value) of foreign substances, of the foreign substances on one substrate SB, which were equal to or more than 1 μm in size was about 10.

### Experimental Example 2

As Experimental Example 2, a deposition process was performed according to a procedure similar to that in Experimental Example 1 except that the rotational angle of the substrate holder 11 rotated by the rotating mechanism 14 at the time of performing a deposition process (see FIG. 2D) was 87°. According to Experimental Example 2, it was measured that the number of foreign substances, of the foreign substances on one substrate SB, which were equal to or more than 1 μm in size was about 8.

### Comparative Example 1

As Comparative Example 1, a deposition process was performed according to a procedure similar to that in Experimental Example 1 except that the area of the placement surface of the receiving portion 121 was increased to make the receiving portion 121 reliably receive the substrate SB at the time of removing the substrate SB from the substrate holder 11 (see FIGS. 2E to 2H). In this case, as the receiving portion 121, a receiving portion having a placement surface whose size was increased (by about 500 μm) in the central direction of the substrate SB as compared with Experimental Example 1 was used. In Comparative Example 1, it was measured that the number of foreign substances, of the foreign substances on one substrate SB, which were equal to or more than 1 μm in size was about 30.

### Comparative Example 2

As Comparative Example 2, a deposition process was performed according to a procedure similar to that in Comparative Example 1 except that the rotational angle of the substrate holder 11 rotated by the rotating mechanism 14 at the time of performing a deposition process (see FIG. 2D) was 87°. In Comparative Example 2, it was measured that the number of foreign substances, of the foreign substances on one substrate SB, which were equal to or more than 1 μm in size was about 24.

As is obvious from the comparison between the measurement results obtained in Experimental Examples 1 and 2 and Comparative Examples 1 and 2, this embodiment can suppress or reduce foreign substances that can accidentally be generated at the time of performing a deposition process by using the deposition apparatus 1, and hence is advantageous in improving the quality of the substrate SB. In addition, although the rotational angle of the substrate holder 11 rotated by the rotating mechanism 14 may be about 90°, the rotational angle according to Experimental Example 2 and Comparative Example 2 may fall within the range of 85° to 89°, preferably, the range of 86° to 88°.

### Application Example

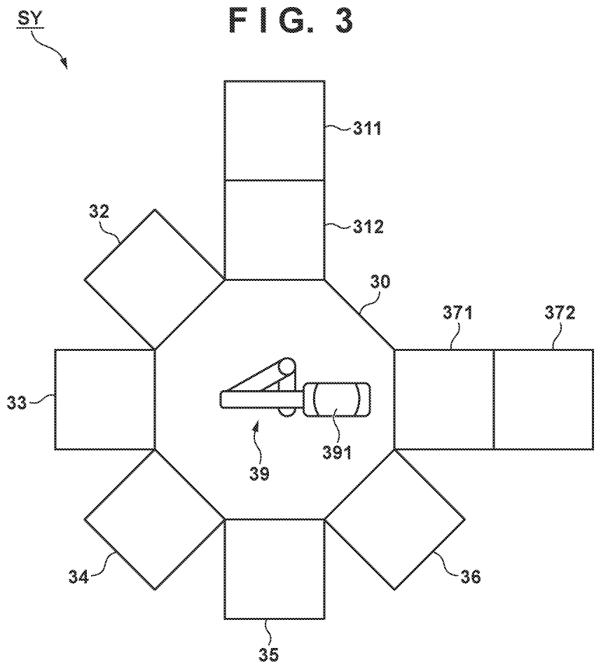

FIG. 3 shows an example of the arrangement of a system SY as an application example of the deposition apparatus 1, which is used to perform a plurality of processes including a deposition process. Assume that in this case, the system SY is a manufacturing system for manufacturing an organic EL (Electro-Luminescence) device as an example of an electronic device. The system SY uses a cluster type arrangement having a plurality of process chambers arranged around a vacuum chamber 30. In this embodiment, the system SY includes a loader 311, a load lock chamber 312, a plurality of chambers 32 to 36, a load lock chamber 371, an unloader 372, and a conveying mechanism 39.

The conveying mechanism 39 is a robot arm provided in the vacuum chamber 30. The conveying mechanism 39 sequentially conveys the substrates SB, supplied from the loader 311 through the load lock chamber 312, to the chambers 32 to 36. Predetermined processes are performed with respect to the substrate SB in the respective chambers 32 to 36. The conveying mechanism 39 then delivers the substrate SB from the unloader 372 to the outside through the load lock chamber 371. This arrangement can perform a series of processes for manufacturing an organic EL device with respect to the substrate SB without making the substrate SB be exposed to the atmosphere (for example, moisture or oxygen) in the time interval from the supply of the substrate SB from the loader 311 to the delivery of the substrate SB from the unloader 372.

The chamber 32 is an inversion chamber (to be referred to as the “inversion chamber 32” hereinafter) that can vertically invert the attitude of the substrate SB conveyed by the conveying mechanism 39. This can change the film formation surface of the substrate SB when performing a deposition process.

The chamber 33 is a vapor deposition chamber (to be referred to as the “organic film vapor deposition chamber 33” hereinafter) that can form an organic compound film on the substrate SB by a vapor deposition method. An organic compound film includes a plurality of layers forming an organic light-emitting element, for example, a light-emitting layer (recombination layer), an electron ejection layer, an electronic transport layer, a hole injection layer, and a hole transport layer.

The chamber 34 is a vapor deposition chamber (to be referred to as the “electrode film vapor deposition chamber 34” hereinafter) that can form an electrode film on the substrate SB by a vapor deposition method. As an electrode film, a translucent or non-translucent conductive material (for example, a metal such as copper or aluminum (Al), an alloy such as a silver (Ag) alloy or magnesium (Mg) alloy, or a transparent metal such as indium tin oxide) may be used.

The chamber 35 is a CVD chamber (to be referred to as the “CVD chamber 35” hereinafter) that can form a functional film on the substrate SB by CVD. Examples of this functional film include insulating films such as a silicon nitride film and a silicon oxynitride film. For example, a silicon nitride film can be formed by plasma CVD using silane, hydrogen, and nitrogen as source gases.

The chamber 36 is an ALD chamber (to be referred to as the “ALD chamber 36” hereinafter) that can form a functional film on the substrate SB by ALD. Examples of this functional film include insulating films such as an aluminum oxide film and a titanium oxide film.

In the system SY described above, the arrangement of the deposition apparatus 1 can be applied to perform, for example, a deposition process by ALD. That is, the chamber 36 corresponds to the chamber 16, and the robot arm as the conveying mechanism 39 corresponds to the conveying mechanism 12.

For example, as the substrate SB, a silicon wafer on which a driving circuit (for example, a plurality of switch elements such as MOS transistors and a wiring portion connecting them) for driving an organic light-emitting element is formed is prepared. The conveying mechanism 39 supplies the substrate SB from the loader 311 into the vacuum chamber 30 through the load lock chamber 312 and conveys the substrate SB to the inversion chamber 32. The substrate SB is set in a desired attitude in the inversion chamber 32. The conveying mechanism 39 then conveys the substrate SB to the organic film vapor deposition chamber 33 to perform a deposition process for an organic compound film.

The conveying mechanism 39 then conveys the substrate SB to the electrode film vapor deposition chamber 34 to perform a deposition process for an electrode film. The conveying mechanism 39 conveys the substrate SB to the inversion chamber 32 to vertically invert the attitude of the substrate SB, and then conveys the substrate SB to the CVD chamber 35 to perform a deposition process for a functional film. Thereafter, the conveying mechanism 39 conveys the substrate SB to the ALD chamber 36 to perform a deposition process for another functional film.

Collaterally, the conveying mechanism 39 may convey the substrate SB to the CVD chamber 35 again to perform a deposition process for still another functional film.

Upon completion of the series of processes with respect to the substrate SB, the conveying mechanism 39 conveys the substrate SB from the unloader 372 to outside the vacuum chamber 30 through the load lock chamber 371, and conveys the substrate SB to the next step. An organic EL device is manufactured by this procedure. The system SY described above may be expressed as a deposition apparatus, manufacturing apparatus, processing apparatus, or the like in a broad sense.

This application example has exemplified the aspect in which an organic EL device is manufactured as an example of an electronic device. However, the contents of the above embodiment can be applied to manufacture various electronic devices. In the system SY further including a plurality of chambers for sequentially processing the substrate SB, the plurality of chambers are configured so as not to make the substrate SB be exposed to the atmosphere until the completion of processes with respect to the substrate SB in the respective chambers. This makes it possible to perform a series of processes with respect to the substrate SB in a substantially vacuum state until a plurality of elements, electric and electronic circuits formed from them, and the like are formed on the substrate SB, that is, until a desired electronic device is manufactured.

This application example makes it possible to suppress or reduce foreign substances that can be accidentally generated when manufacturing an electronic device by a series of processes including a deposition process. This is advantageous in improving the quality of the substrate SB and collaterally improving the quality of the electronic device.

### Experimental Example 3

As an example of the above application example, in Experimental Example 3, 25 silicon wafers were prepared as the substrates SB, and an organic EL device was manufactured from the substrates SB by using the system SY (see FIG. 3). The substrates SB were integrally stored in a cassette and simultaneously supplied by the loader 311. In addition, the substrates SB were integrally stored in the cassette and simultaneously transferred by the unloader 372. In the ALD chamber 36, an aluminum oxide film was formed by a procedure similar to that in Experimental Example 1. That is, a deposition process was performed at a substrate temperature of 100° C. by ALD using trimethylaluminum (TMA) and water vapor (H₂O).

The rotational angle of the substrate holder 11 rotated by the rotating mechanism 14 at the time of performing a deposition process (see FIG. 2D) was set to 90°. A gap of about 500 μm was provided between the substrate SB and the inner wall of the housing at the time of inserting the substrate SB into the substrate holder 11 (see FIGS. 2A to 2C). Accordingly, the stop position of the conveying mechanism 12 (for example, P2 or P9) at the time of removing the substrate SB from the substrate holder 11 (see FIGS. 2E to 2H) was located more backward by about 500 μm than the stop position (for example, P1) of the conveying mechanism 12 at the time of inserting the substrate SB.

When a lighting test was conducted concerning the organic EL devices obtained in Experimental Example 3, the defective rate in the lighting test was able to be suppressed to about 12%.

### Experimental Example 4

As Experimental Example 4, a deposition process was performed according to a procedure similar to that in Experimental Example 3 except that the rotational angle of the substrate holder 11 rotated by the rotating mechanism 14 at the time of performing a deposition process (see FIG. 2D) was 87°. In Experimental Example 4, the defective rate in a lighting test was able to be suppressed to about 8%.

### Comparative Example 3

As Comparative Example 3, a deposition process was performed according to a procedure similar to that in Experimental Example 3 except that the area of the placement surface of the receiving portion 121 was increased to make the receiving portion 121 reliably receive the substrate SB at the time of removing the substrate SB from the substrate holder 11 (see FIGS. 2E to 2H). In this case, as the receiving portion 121, a receiving portion having a placement surface whose size was increased (by about 500 μm) in the central direction of the substrate SB as compared with Experimental Example 3 was used. In Comparative Example 3, the defective rate in a lighting test was about 28%.

### Comparative Example 4

As Comparative Example 4, a deposition process was performed according to a procedure similar to that in Comparative Example 3 except that the rotational angle of the substrate holder 11 rotated by the rotating mechanism 14 at the time of performing a deposition process (see FIG. 2D) was 87°. In Comparative Example 4, the defective rate in a lighting test was about 24%.

As is obvious from Experimental Examples 3 and 4 and Comparative Examples 3 and 4 described above, this application example makes it possible to suppress or reduce foreign substances that can be accidentally generated when manufacturing an electronic device by a series of processes including a deposition process. This is advantageous in improving the quality of the electronic device.

### OTHER EMBODIMENTS

Although several preferred aspects have been described above, the present invention is not limited to them, and the examples may be partly changed without departing from the spirit of the present invention. In addition, each term in this specification is merely used to explain the present invention, and the present invention is not limited to the strict meaning of the term. Although the embodiment has been described, focusing on a deposition process by the deposition apparatus 1, the embodiment can also be applied to other semiconductor manufacturing processes such as an etching process and a cleaning process.

Embodiment(s) of the present invention can also be realized by a computer of a system or apparatus that reads out and executes computer executable instructions (e.g., one or more programs) recorded on a storage medium (which may also be referred to more fully as a ‘non-transitory computer-readable storage medium’) to perform the functions of one or more of the above-described embodiment(s) and/or that includes one or more circuits (e.g., application specific integrated circuit (ASIC)) for performing the functions of one or more of the above-described embodiment(s), and by a method performed by the computer of the system or apparatus by, for example, reading out and executing the computer executable instructions from the storage medium to perform the functions of one or more of the above-described embodiment(s) and/or controlling the one or more circuits to perform the functions of one or more of the above-described embodiment(s). The computer may comprise one or more processors (e.g., central processing unit (CPU), micro processing unit (MPU)) and may include a network of separate computers or separate processors to read out and execute the computer executable instructions. The computer executable instructions may be provided to the computer, for example, from a network or the storage medium. The storage medium may include, for example, one or more of a hard disk, a random-access memory (RAM), a read only memory (ROM), a storage of distributed computing systems, an optical disk (such as a compact disc (CD), digital versatile disc (DVD), or Blu-ray Disc (BD)™), a flash memory device, a memory card, and the like.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent Application No. 2019-100726, filed on May 29, 2019, which is hereby incorporated by reference herein in its entirety.

What is claimed is:

1. A deposition apparatus comprising:
a substrate holder configured to be able to hold a substrate;
a conveying mechanism configured to convey the substrate in a horizontal attitude and to be able to insert and remove the substrate into and from the substrate holder;
a rotating mechanism configured to change an attitude of the substrate held by the substrate holder by rotating the substrate holder;
a chamber configured to accommodate the substrate holder rotated by the rotating mechanism so as to set the substrate in a vertical attitude and to perform a deposition process with respect to the substrate; and
a control unit,
wherein the control unit performs first control to cause the conveying mechanism to make the substrate holder hold the substrate at a first position when inserting the substrate into the substrate holder before the deposition process, and
performs second control to cause the conveying mechanism to receive the substrate from the substrate holder at a second position located more backward than the first position when removing the substrate from the substrate holder after the deposition process.

2. The apparatus according to claim 1, wherein
the substrate is one of a plurality of substrates,
the substrate holder can hold the plurality of substrates, and
the control unit controls the conveying mechanism and the rotating mechanism in the first control so as to set each of the plurality of substrates in a horizontal attitude and cause the substrate holder to hold the substrates arranged in a vertical direction.

3. The apparatus according to claim 1, wherein the substrate holder includes a first supporting portion supporting the substrate in a vertical attitude on a lower side and a second supporting portion supporting the substrate on a lateral side, and the first supporting portion is located on an opposite side to a side where the conveying mechanism accesses the substrate holder relative to the second supporting portion while the substrate holder holds the substrate in a horizontal attitude.

4. The apparatus according to claim 1, wherein the chamber performs at least one of CVD (Chemical Vapor Deposition) and ALD (Atomic Layer Deposition) as the deposition process.

5. The apparatus according to claim 1, further comprising a moving mechanism configured to move the substrate holder between an accessible position of the conveying mechanism with respect to the substrate holder and a position in the chamber.

6. The apparatus according to claim 5, wherein the moving mechanism is a lifting mechanism, and
the chamber is located below the accessible position of the conveying mechanism with respect to the substrate holder.

7. The apparatus according to claim 5, wherein the moving mechanism is a lifting mechanism, and
the chamber is located above the accessible position of the conveying mechanism with respect to the substrate holder.

8. The apparatus according to claim 1, further comprising a second chamber configured to perform another process with respect to the substrate, with the chamber being a first chamber,
wherein the first chamber and the second chamber are configured to prevent the substrate from being exposed to an atmosphere until a process is completed with respect to the substrate in each of the chambers.

9. A deposition method comprising:
causing a substrate holder to hold a substrate at a first position while causing a conveying mechanism to convey the substrate in a horizontal attitude;
performing a deposition process with respect to the substrate after the substrate held by the substrate holder is set in a vertical attitude by causing a rotating mechanism to rotate the substrate holder;
returning the substrate held by the substrate holder to a horizontal attitude by causing the rotating mechanism to rotate the substrate holder; and
causing the conveying mechanism to receive the substrate from the substrate holder at a second position located more backward than the first position.
